(19) United States
(12) Patent Application Publication
(10) Pub. No.: US 2010/0193847 A1
(43) Pub. Date: Aug. 5, 2010

(54) METAL GATE TRANSISTOR WITH BARRIER LAYER

(75) Inventors: Zhi-Xiong Jiang, Austin, TX (US); Kyuhwan H. Chang, Austin, TX (US); Kiwoon Kim, Round Rock, TX (US)

Correspondence Address: FSI;c/o JACKSON WALKER, L.L.P., 100 CONGRESS AVENUE, SUITE 1100, AUSTIN, TX, 78701, US

(73) Assignee: FREESCALE SEMICONDUCTOR, INC., Austin, TX (US)

(21) Appl. No.: 12/362,743

(22) Filed: Jan. 30, 2009

(51) Int. Cl. H01L 29/78; H01L 21/283; H01L 21/336; H01L 29/43

(52) U.S. Cl. 257/288; 438/585; 257/E21.159; 257/E29.255; 257/E21.409; 257/E29.139

(57) ABSTRACT

A semiconductor fabrication process for forming a gate electrode for a metal-oxide-semiconductor (MOS) transistor includes forming a gate electrode layer of an electrically conductive ceramic, e.g., titanium nitride, overlying a gate dielectric layer, e.g., a high K dielectric. A gate barrier layer is then formed overlying the gate electrode layer. The gate barrier layer may be a metal or transition metal material including, as an example, titanium. Portions of the gate electrode layer and the gate barrier layer are then etched or otherwise removed to form the gate electrode.

### BACKGROUND

1. Field

The disclosed subject matter is in the field of semiconductor fabrication processes and, more particularly, semiconductor fabrication processes that employ metal gate transistors.

2. Related Art

Metal gate transistors have replaced polysilicon gate transistors in some advanced fabrication processes. Metal gate transistors have higher conductivity than polysilicon gates. In addition, metal gates do not exhibit depletion effects that are common to polysilicon gates. Tantalum, tantalum nitride, and tungsten have all been used as materials for metal gate transistors.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a partial cross sectional view of a wafer at a selected stage in an embodiment of a semiconductor fabrication process, the depicted stage illustrating the formation of a gate dielectric overlying a semiconductor substrate;

FIG. 2 depicts processing subsequent to FIG. 1 including the formation of a gate electrode layer overlying the gate dielectric layer;

FIG. 3 depicts processing subsequent to FIG. 2 including the formation of a gate barrier layer overlying the gate electrode layer;

FIG. 4 depicts processing subsequent to FIG. 3 illustrating the formation of a gate electrode, source/drain extensions, and source/drain regions;

FIG. 5 depicts additional detail of a portion of FIG. 4 emphasizing the appearance of a native oxide overlying the gate barrier layer; and

FIG. 6 depicts processing subsequent to FIG. 4 including the formation of backend structures, including interlevel dielectric layers and interconnect layers, to complete an integrated circuit.

### DETAILED DESCRIPTION

In one aspect, a semiconductor fabrication process for forming a gate electrode for a metal-oxide-semiconductor (MOS) transistor includes forming a gate electrode layer overlying a gate dielectric layer. A gate barrier layer is then formed overlying the gate electrode layer. Portions of the gate electrode layer and the gate barrier layer are then etched or otherwise removed to form the gate electrode.

The gate dielectric layer overlies an active region of a semiconductor substrate. In some embodiments, the gate dielectric layer has an effective oxide thickness (EOT) in the range of approximately 1 to approximately 5 nm. The gate dielectric layer may include a high-K dielectric material, e.g., a high-K metal oxide such as HfO, thermally formed silicon dioxide, a different silicon-oxide compound, or a combination thereof.

A thickness of the gate electrode layer may be in the range of approximately 10 to approximately 50 nm. The gate electrode layer material may be an electrically conductive, non-oxide, ceramic material. In some embodiments, for example, the gate electrode material is or includes titanium nitride (TiN). The gate electrode layer may be deposited using chemical vapor deposition, physical vapor deposition, or another suitable deposition process.

In some embodiments, the presence of the gate barrier layer beneficially provides a moisture barrier and a barrier to the migration of other unintended impurities, including oxygen and hydrogen, from an interlevel dielectric layer or interconnect layer overlying the gate barrier layer to the gate electrode layer. A thickness of the gate barrier layer may be in the range of approximately 1 to approximately 5 nm. The gate barrier layer may be formed on or directly over the top of the gate electrode layer. For example, the formation of the gate electrode layer may occur in a deposition chamber that is sealed from the atmosphere and the subsequent formation of the gate barrier layer may occur without exposing the wafer to the atmosphere. In some embodiments, the gate barrier layer is or includes a transition metal material including, e.g., titanium.

Disclosed processes may further include, prior to forming the gate electrode layer, forming the gate dielectric layer overlying an active region of a semiconductor substrate. Following the formation of the gate electrode, some embodiments may further include the formation of source/drain extensions, the formation of dielectric spacer structures on sidewalls of the gate electrode, and the formation of source/drain regions. Thereafter, some embodiments may further include the formation of one or more interlevel dielectric layers and the formation of one or more interconnect layers, also sometimes referred to as metallization layers, to form an integrated circuit by interconnecting a plurality of transistors in a desired manner.

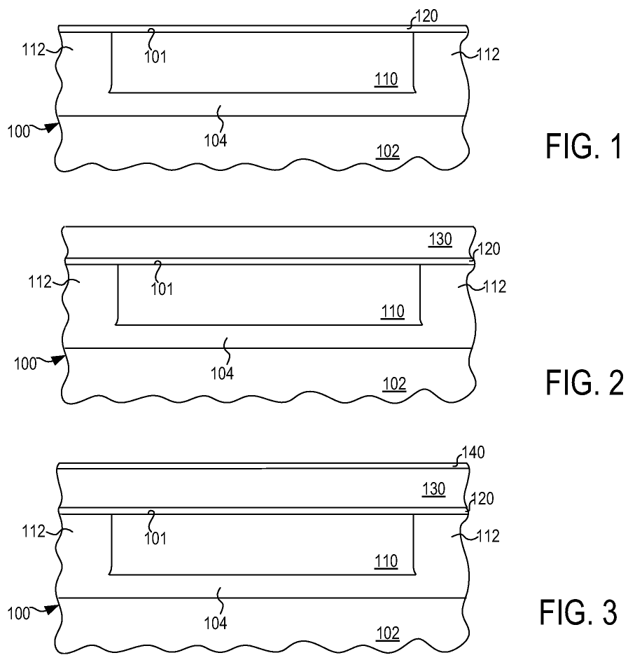

Turning now to the drawings, FIG. 1 is a partial, cross sectional view of a wafer 100 at a selected stage in an embodiment of a semiconductor fabrication process. In some embodiments, wafer 100 is a silicon-on-insulator (SOI) wafer including a semiconductor substrate bulk 102 and a substrate isolation layer 104 overlying substrate bulk 102. Substrate bulk 102 may include or consist of a semiconductor material, e.g., silicon or germanium, or a semiconductor compound, e.g., gallium arsenide. Substrate isolation layer 104 may be formed by the wafer manufacturer using well known SOI techniques. Substrate isolation layer 104 is, in some embodiments, a silicon-oxide compound exhibiting the characteristics of an electrical insulator.

Wafer 100 as depicted in FIG. 1 further includes an active region 110 positioned between a pair of shallow trench isolation (STI) structures 112. In some embodiments, active region 110 represents a remaining portion of an active layer formed on SOI wafer 100. In these embodiments, the active layer may be formed using an epitaxial process that produces a high quality, low defect crystalline lattice. Active region 110 may be doped n-type or p-type depending upon the application and the implementation. In addition, active region 110 may include other intended impurities to influence its mechanical and/or electrical behavior. In silicon implementations of active region 110, for example, portions of active region 110 may include impurities such as arsenic, boron, or phosphorous for selectively controlling the conductivity and polarity of active region 110. Active region 110 may also include other intended impurities such as germanium and/or silicon carbide for manipulating stress gradients in active region 110 as well as other impurities for other purposes.

In other embodiments, wafer 100 be implemented with a non-SOI configuration. For example, wafer 100 could be implemented without the substrate isolation 104 and forming active region 110 overlying substrate bulk 102, which could be bulk silicon.

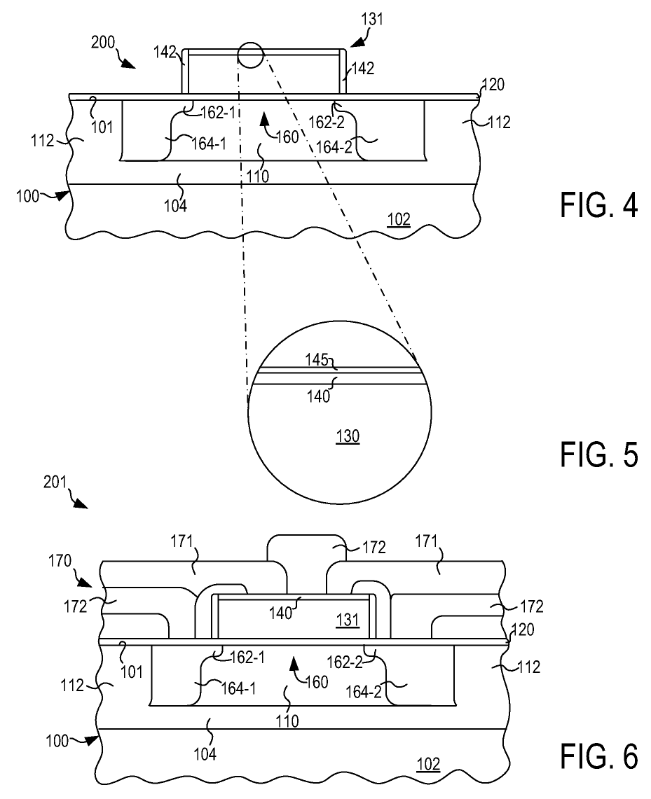

Active region 110 represents a region of wafer 100 in which an MOS transistor 200 (FIG. 4) of an integrated circuit 201 (FIG. 6) is or will be formed. In some embodiments, an exemplary dimension for a thickness of active region 110 may be in the range of approximately 50 to 200 nm. Other embodiments may have different dimensions. Active region 110 may be formed by depositing a layer of the material or materials used for active region 110 and thereafter, using conventional photolithography and etch techniques, selectively removing portions of the active layer where STI structures 112 are to be located. STI structures 112 may be or include a silicon oxide compound, another electrically insulating material, or a combination thereof. For example, STI structures 112 may be formed by CVD using tetraethyl orthosilicate (TEOS) or another suitable gas as a source.

FIG. 1 also depicts a gate dielectric layer 120 formed overlying an upper surface 101 of wafer 100. Gate dielectric layer 120 may include any suitable electrically insulating material such as any of various silicon-oxide compounds including thermally-formed silicon dioxide, a “high K” dielectric, e.g., a hafnium oxide, or another metal-oxide compound, or a combination thereof. In some embodiments, an effective oxide thickness (EOT) of gate dielectric layer 120 is in the range of approximately 1 to approximately 5 nm, but gate dielectric layer 120 may have other thicknesses in other embodiments. As used in this disclosure, a high K dielectric refers to a material having a dielectric constant of greater than approximately 2.

Referring now to FIG. 2, a subsequent stage in the processing of wafer 100 is depicted. As depicted in FIG. 2, a gate electrode layer 130 has been formed overlying and in contact with gate dielectric layer 120. In some embodiments, gate electrode layer 130 may include an electrically conductive, non-oxide, ceramic material. Exemplary candidates for gate electrode layer 130 include suitable metal-carbides, metal-nitrides, and metal-silicides. The metal material selected may include a Group 4 metal such as titanium, zirconium, or hafnium, a Group 5 metal such as vanadium or tantalum, or a combination thereof. Gate electrode layer 130 may, for example, include a metal-nitride compound such as titanium nitride, titanium carbon nitride, titanium aluminum nitride, or another suitable metal nitride. The thickness of gate electrode layer 130 is an implementation detail, but some embodiments may employ a gate electrode layer 130 having a thickness in the range of approximate 10 to 50 nm.

Referring now to FIG. 3, a gate barrier layer 140 has been formed on gate electrode layer 130. Gate barrier layer 140, as its name suggests, is designed to act as a barrier to impurities including moisture and hydrogen thereby preventing the impurities from migrating into gate electrode layer 130. Gate barrier layer 140 may be a thin layer relative to gate electrode layer 130. Gate barrier layer 140 may, for example, have a thickness in the range of approximately 1 nm to 5 nm.

Gate barrier layer 140 may include or consist entirely or substantially of a metal or transition metal material. In some embodiments, for example, gate barrier layer 140 may include or consist entirely of one or more metals such as titanium, zirconium, hafnium, vanadium, or tantalum.

In some embodiments, it is desirable to fabricate gate barrier layer 140 in a manner that impedes the formation of a native oxide overlying gate electrode layer 130. In some embodiments, for example, gate electrode layer 130 and gate barrier layer 140 are formed in successive deposition processes within a single piece of deposition equipment without exposing wafer 100 to atmosphere between the deposition of gate electrode layer 130 and the deposition of gate barrier layer 140. In other embodiments, the formation of gate barrier layer 140 may be immediately preceded by a wet and/or dry etch process intended to remove native oxide films that form on gate electrode layer 130.

In some embodiments, depositing gate electrode layer 130 and gate barrier layer 140 without exposing the wafer to atmosphere is facilitated by using a common metal material for gate electrode layer 130 and gate barrier layer 140. In these embodiments, sputtering or another physical vapor deposition process may be used to deposit gate electrode layer 130 and gate barrier layer 140 using a common target. For example, in an embodiment having a TiN gate electrode layer 130 and a titanium gate barrier layer 140, deposition of gate electrode layer 130 may include a sputtering process using a titanium target in high energy, nitrogen bearing environment. The deposition of gate barrier layer 140 may then be achieved by purging the nitrogen from the deposition chamber and thereafter continuing the titanium target sputtering in an argon or other inert environment. Similarly, gate electrode layer 130 and gate barrier layer 140 may be formed used chemical vapor deposition (CVD) processes. In an CVD embodiment that employs TiN for gate electrode 130 and titanium for gate barrier layer 140, it may be feasible and desirable to form gate electrode layer 130 in a nitrogen bearing deposition and thereafter terminating the supply of the nitrogen source and depositing the titanium gate barrier layer. In still other embodiments, the deposition of gate electrode layer 130 and gate barrier layer 140, whether by PVD or CVD, occurs in different chambers of a single deposition tool. In still other embodiments, either gate electrode layer 130 or gate barrier layer 140 may be formed using CVD while the other of the two layers is formed using PVD.

Referring now to FIG. 4, additional processing subsequent to FIG. 3 results in the formation of a MOS transistor 200. Portions of gate electrode layer 130 and gate barrier layer 140 have been etched or otherwise removed and dielectric spacers 142 have been formed on sidewalls of gate electrode layer 130 to produce a gate electrode 131 of MOS transistor 200. In a variation of the depicted embodiment, a layer of a semiconductor material such as polycrystalline silicon may be formed overlying gate barrier layer 140, either before or after the processing depicted in FIG. 4. In this embodiment, the semiconductor layer overlying gate electrode 131 may ultimately function as a part of the gate electrode.

In addition to the formation of gate electrode 131, FIG. 4 further illustrates the formation of source/drain structures including lightly doped S/D extensions 162 and heavily doped source/drain structures 164, both of which are self aligned to gate electrode 131. LDD regions 162 and S/D regions 164 may be n-type or p-type depending upon the implementation.

FIG. 5 details a portion of gate electrode 131 at the interface between gate barrier layer 140 and gate electrode layer 130. As shown in FIG. 5, native oxide 145 has formed overlying gate barrier layer 140. In some embodiments, the formation of native oxide 145 may be desirable in terms of preventing moisture and other unwanted impurities from reaching gate electrode layer 130. In some embodiments, native oxide 145 as well as gate barrier layer 140 may be entirely or partially etched away or otherwise removed prior to performing backend processing.

FIG. 6 depicts wafer 100 after formation of backend structures 170 overlying wafer 101 including gate electrode 131. In the depicted embodiment, backend structures 170 may include one or more interlevel dielectric layers (ILDs) such as the ILDs 171 illustrated in FIG. 6. ILDs 171 may include silicon oxide or another suitable electrical insulator. Also depicted in backend 170 are one or more layers of electrically conductive interconnect 172, sometimes also referred to as metallization 172. Materials suitable for use in fabricating interconnects 172 include copper, aluminum, and so forth, and may include barrier layers. Thus, as can be seen in FIG. 6, the upper portion of gate electrode 131 is in contact with or virtual contact with and underlies a portion of a metallic interconnect 172 and portions of an ILD structure 171.

FIG. 6 depicts transistor 200 and integrated circuit 201 with all or some of the gate barrier layer 140 still intact overlying gate electrode layer 130. In some embodiments, including embodiments such as those depicted in FIG. 5 wherein a native oxide 145 forms on an upper surface of gate barrier layer 140, portions of native oxide 145 and/or gate barrier layer 140 may be etched away or otherwise removed prior to the formation of backend 170. Thus, although FIG. 6 depicts the presence of gate barrier layer 140, other embodiments may elect to etch or otherwise remove gate barrier layer 140 as well as native oxide 145. In the embodiment depicted, the presence of gate barrier layer 140 overlying gate electrode 131 beneficially prohibits or reduces migration of moisture, hydrogen, oxygen, and other impurities from metallic interconnect 172 and/or ILD structure 171 into gate electrode 131.

Although the invention is described herein with reference to specific embodiments, various modifications and changes can be made without departing from the scope of the present invention as set forth in the claims below. For example, although the illustrated embodiments employ an SOI wafer 100 as the starting material other embodiments may employ a bulk silicon starting material. Similarly, although the depicted embodiments emphasize the gate electrode as the element benefiting from the barrier layer, other embodiments may employ a similar structure in back end processing including, for example, in the metallization layers. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements.

1. A semiconductor fabrication process for forming a transistor, comprising:
forming an electrically conductive gate electrode layer overlying a gate dielectric layer, wherein the gate electrode layer comprises a compound including a metal species and a nitrogen species;
forming a gate barrier layer on the gate electrode layer wherein the gate barrier layer consists substantially of the metal species; and
after forming the gate barrier layer, patterning the gate electrode layer to form a gate electrode for the transistor.

2. The process of claim 1, further comprising, prior to forming the gate electrode layer, forming the gate dielectric layer overlying an active region of a semiconductor substrate.

3. The process of claim 1, wherein the metal species is selected from the group consisting of titanium, zirconium, hafnium, vanadium, and tantalum.

4. The process of claim 3, wherein the gate electrode layer compound comprises titanium nitride.

5. (canceled)

6. The process of claim 4, wherein forming the gate electrode layer occurs in a vacuum chamber and wherein forming the gate barrier layer occurs before the gate electrode layer is exposed to atmosphere.

7. The process of claim 1, wherein a thickness of the gate barrier layer is in the range of approximately 1 to approximately 5 nm.

8. The process of claim 1, further comprising, after forming the gate barrier layer, forming at least one of an interlevel dielectric (ILD) layer and an interconnect layer overlying the gate electrode layer.

9. The process of claim 8, further comprising, prior to forming the ILD or the interconnect layer, removing a native oxide film formed on the gate barrier layer.

10. The process of claim 9, further comprising, prior to forming the ILD or the interconnect layer, removing at least a portion of the gate barrier layer formed on the gate electrode layer.

11-16. (canceled)

17. A transistor fabrication process, comprising:
forming a gate dielectric layer overlying an active region of a semiconductor substrate; and
while maintaining the wafer in a vacuum chamber:
forming a titanium nitride gate electrode layer overlying the gate dielectric layer; and
forming a titanium gate barrier layer overlying the gate electrode layer; and
after forming the gate barrier layer, removing portions of the gate electrode layer to form a gate electrode.

18. The process of claim 17, wherein the forming of a gate barrier layer comprises forming a gate barrier layer having a thickness in the range of 1 to 5 nm.

19. The process of claim 17, further comprising:
prior to forming a structure overlying the gate electrode, removing a native oxide formed on the gate barrier layer; and
after removing the native oxide, forming a backend structure overlying the gate electrode, wherein the backend structure includes at least one of an interlevel dielectric layer and an interconnect layer.

20. The process of claim 17, wherein the removing of the native oxide includes at removing or partially removing the gate barrier layer.

21. A semiconductor fabrication process, comprising:
forming a layer of a metal compound on a gate dielectric layer, wherein the metal compound is selected from the group consisting of a metal-nitride compound, a metal-silicide compound, and a metal-carbide compound and further wherein the metal compound includes a metal species;
forming a layer of the metal species overlying the metal compound layer; and
patterning the metal compound layer to form a gate electrode.

22. The process of claim 21, wherein an effective oxide thickness of the gate dielectric layer is in the range of approximately 1 to approximately 5 nm, and wherein a thickness of the metal compound layer is in the range of approximately 10 to approximately 50 nm.

23. The process of claim 22, wherein a thickness of the metal species layer is in the range of approximately 1 nm to approximately 5 nm.

24. The process of claim 21, wherein the metal species is selected from the group consisting of titanium, zirconium, hafnium, vanadium, and tantalum.

25. The process of claim 24, wherein the metal species is titanium.

26. The process of claim 25, wherein the metal compound comprises one of titanium nitride, titanium carbon nitride, and titanium aluminum nitride.
